(19) United States
(12) Patent Application Publication
(10) Pub. No.: US 2002/0119672 A1
(43) Pub. Date: Aug. 29, 2002

(54) Post-etching cleaning process in dual damascene structure manufacturing

(76) Inventors: Chih-Ning Wu, Hsinchu (TW); Sun-Chieh Chien, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/795,754

(22) Filed: Feb. 28, 2001

(51) Int. Cl. H01L 21/302; H01L 21/461

(52) U.S. Cl. 438/745

(57) ABSTRACT

A post-etching cleaning method for removing high molecular weight compounds formed after an etching operation. After a dual damascene opening is formed by etching a dielectric layer over a substrate, a two-stage wet cleaning operation is conducted. In the first wet cleaning, a cleaning solution is used to wash the substrate. The cleaning solution contains hydrogen peroxide and benzotriazole. In the second wet cleaning, inorganic acid solution is used.

### BACKGROUND OF THE INVENTION

1. Field of Invention

The present invention relates to a post-etching cleaning method. More particularly, the present invention relates to a post-etching cleaning process in dual damascene structure manufacturing.

2. Description of Related Art

In the semiconductor industry, increasing the operating speed of a semiconductor device is always one of the main goals. Following the rapid progress in fabrication technologies, many types of fast-operating integrated circuits are being produced. However, a persistent factor that still brings down the operating speed of an integrated circuit is the resistance-capacitance delay (RC delay) caused by resistance of conductive lines and parasitic capacitance between conductive lines. At present, a low-resistant metallic material can be used to reduce conductive line resistance. In addition, a low dielectric constant material can be used to form the inter-layer dielectric layer, thereby reducing parasitic capacitance between conductive lines.

Dual damascene process is a method of forming metallic interconnects. The dual damascene process involves the etching out of a trench and a via hole in a dielectric layer followed by the re-filling of the trench and the via hole with a metallic layer. Dual damascene process is not only a low-cost and highly reliable method of forming interconnects, but the type of material used for re-filling the trench and the via opening is also unrestricted by the etching process. Hence, the technique is now widely adopted in the formation of copper lines for reducing conductive line resistance and increasing the operating speed of devices. As the demand for higher operating speed semiconductor products increases, more integrated circuits are fabricated by dual damascene process using low dielectric constant material.

FIG. 1 is a schematic cross-sectional view of a semiconductor device having a conventional dual damascene structure. To form a conventional dual damascene structure, a substrate 10 having a metallic layer 12 thereon is provided. A silicon nitride layer 14 and a dielectric layer 16 are sequentially formed over the substrate 10. The dielectric layer 16 is patterned and then etched to form a dual damascene opening 18. Thereafter, the silicon nitride layer 14 above the metallic layer 12 is etched using an anisotropic etching gaseous mixture such as difluoromethane (CH₂F₂)/oxygen/argon so that the top surface of the metallic layer 12 is exposed. During the etching step, a large amount of high molecular weight polymeric material 20 is produced which adheres to the exposed dielectric layer 16 inside the opening 18 and on the surface of the metallic layer 12. The high molecular weight polymeric residues as well as organic material deposited on the metallic layer is preferably removed in a cleaning process before refilling the opening 18 with a metallic material. After a thorough cleaning, metallic material is deposited into the opening 18 and then a chemical-mechanical polishing operation is conducted to remove excess metal above the dielectric layer 16.

Typically, residual material inside the opening 18 is removed by washing with a hydrofluoric acid (H₂O:HF=100:1˜40) solution. However, this solution is incapable of completely removing the attached high molecular weight residues 20 and other organic materials, ultimately leading to a higher via contact resistance. In addition, a hydrofluoric acid solution having a high concentration is used. Moreover, the hydrofluoric acid solution is applied for more than 10 minutes. Undercutting of the silicon nitride layer 14 may occur leading to the formation of a recess cavity 22 between the dielectric layer 16 and the metallic layer 12. The recess cavity 22 prevents the proper filling of metallic material in subsequent deposition and ultimately may lead to device reliability problems.

### SUMMARY OF THE INVENTION

Accordingly, one object of the present invention is to provide a post-etching cleaning method capable of removing residual high molecular weight polymeric material and organic material.

A second object of this invention is to provide a post-etching cleaning method for a dual damascene process capable of removing residual high molecular weight polymeric material and organic material so that contact resistance of a via is reduced.

A third object of this invention is to provide a post-etching cleaning method capable of preventing the undercutting of a cap layer.

To achieve these and other advantages and in accordance with the purpose of the invention, as embodied and broadly described herein, the invention provides a post-etching cleaning method for removing polymeric compounds formed after an etching operation. After a dual damascene opening is formed by etching a dielectric layer above a substrate, a two-stage wet cleaning operation is conducted. In a first wet cleaning, a cleaning solution is used to wash the substrate. The cleaning solution contains an oxidizing agent and a testing agent. The testing agent is a chemical substance capable of reducing the rate of oxidation between the oxidizing agent and the metal in the metallic layer. A second wet etching is next carried out using an inorganic acid solution.

In the preferred embodiment of this invention, the oxidizing agent is capable of oxidizing the high molecular weight polymeric residues and the organic material on the metallic layer. The oxidizing agent used in the first wet etching stage is preferably a hydrogen peroxide (H₂O₂) solution. The volumetric ratio between hydrogen peroxide and water in the hydrogen peroxide solution is preferably between 1:80 to 1:25. The testing agent or amalgamating agent used for reducing the oxidation of metal in the metallic layer and the oxidizing agent is preferably benzotriazole (BTA) with a concentration of between 0.5 ppm to 5 ppm. The inorganic acid solution is preferably a diluted hydrofluoric acid solution. The inorganic acid solution is capable of micro-etching the oxidized portion of the metallic layer so that the underlying fresh metal is re-exposed again. The volumetric ratio between hydrofluoric acid and water in the hydrofluoric acid solution is preferably between 1:600 to 1:500.

In this invention, a two-stage wet etching process is employed. The two-stage wet etching is capable of removing residual polymeric compounds deposited during the etching of a dielectric layer, and also organic compounds on the metallic layer, so that a via having a relatively low contact resistance is subsequently formed. In addition, the post-etching cleaning method is capable of preventing the undercutting of cap layer. Moreover, the two-stage wet etching process is capable of minimizing cavity-forming reactions resulting in the formation of a highly planar metallic surface after the cleaning step.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a semiconductor device having a conventional dual damascene structure;

FIG. 2 is a schematic cross-sectional view of a semiconductor device having a dual damascene structure fabricated according to the embodiment of this invention;

FIG. 3 is a schematic cross-sectional view of a semiconductor device having a via hole structure fabricated according to the embodiment of this invention;

FIG. 4 is a schematic cross-sectional view of a semiconductor device having a trench structure fabricated according to the embodiment of this invention; and

FIG. 5 is a flow chart showing the cleaning steps after etching the dielectric layer and the cap layer according to the embodiment of this invention.

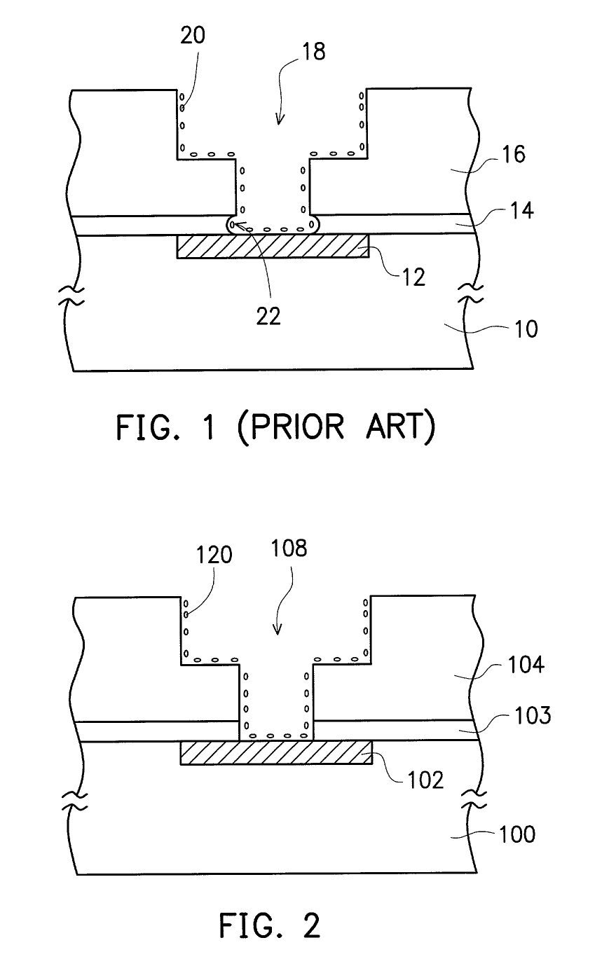

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

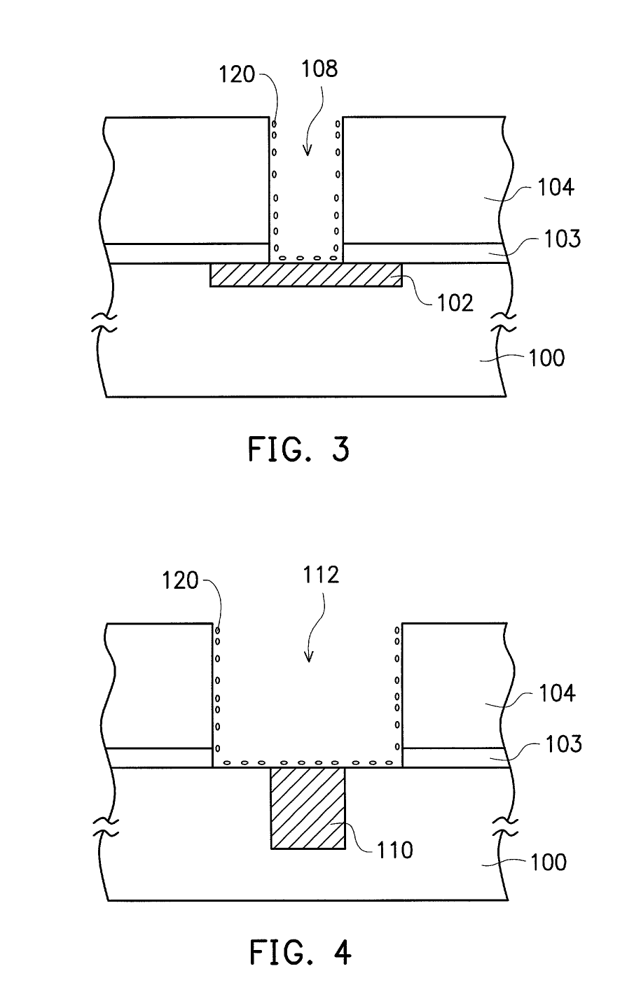

The post-etching cleaning method of this invention is suitable for clearing away residual compounds in a dual damascene process after a dielectric layer and a cap layer are etched. However, the method of this invention is not limited to the fabrication of interconnects in a dual damascene process as shown in FIG. 2. The method is equally applicable in other cases including the formation of a via hole and a trench in a dielectric layer as shown in FIGS. 3 and 4. In FIG. 2, a dual damascene opening 106 that exposes a portion of the metallic layer 102 is formed by etching the dielectric layer 104 and the cap layer 103 over a substrate 100. In FIG. 3, a via hole 108 that exposes a portion of the metallic layer 102 is formed by etching the dielectric layer 104 and the cap layer 103 over a substrate 100. In FIG. 4, a trench 112 is formed in the dielectric layer 104 and the cap layer 103 over a substrate 100. The trench 112 exposes a via/contact 110 in the substrate 100 so that a metallic line is subsequently formed after depositing metallic material into the trench 112. The dielectric layer 104 in FIGS. 2, 3 and 4 can be, for example, a high molecular weight low dielectric constant compound formed by spin-coating. The cap layer 103 can be, for example, a silicon nitride layer formed by chemical vapor deposition. The metallic layer 102 or the via/contact 110 can be, for example, a copper layer. The gaseous source for carrying out the etching of the dielectric layer 104 can be, for example, a nitrogen/hydrogen mixture, a nitrogen/oxygen mixture or simply argon. The gaseous source for carrying out the etching of the cap layer 103 can be, for example, a difluoromethane/oxygen/argon mixture. When the cap layer 103 is etched, high molecular weight polymeric residues 120 are normally formed on the sidewalls and bottom of the dual damascene opening 106, the contact/via opening 108 and the trench 112.

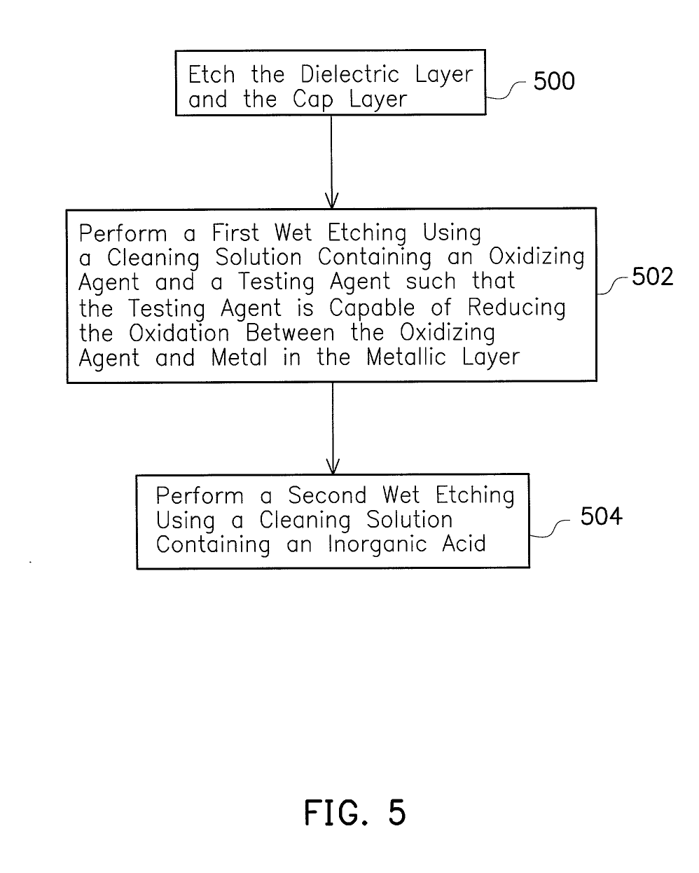

FIG. 5 is a flow chart showing the cleaning steps after etching the dielectric layer and the cap layer according to the embodiment of this invention. After the step of forming the dual damascene opening 106, the via hole 108 or the trench 112 in step 500, a two-stage wet etching process is conducted. In the first stage wet etching step 502, a cleaning solution that contains an oxidizing agent and a testing agent is used. The testing agent is a chemical compound that can slow the oxidation between the oxidizing agent and metal in either the metallic layer 102 or the via/contact 110. In the second stage wet etching step 504, an inorganic acid solution is used.

The oxidizing agent in the first stage wet etching step 502 is able to oxidize the high molecular weight compound on the metallic layer 102 or the organic compound on the via/contact 110 formed during the etching step. The oxidizing agent is preferably hydrogen peroxide. The volumetric ratio between hydrogen peroxide and water in the hydrogen peroxide solution is between 1:80 to 1:25. The testing agent can be a amalgamating agent capable of reducing the oxidation between the oxidizing agent and the metal in the metallic layer 102 or the via/contact 110. The testing agent is preferably benzotriazole (BTA) having a concentration of between 0.5 ppm to 5 ppm. The inorganic acid solution is preferably a diluted hydrofluoric acid solution. The inorganic acid solution used in the second stage wet etching step 504 is capable of micro-etching the oxidized portion of the metallic layer 102 or the via/contact 110. Ultimately, the underlying fresh metal in the metallic layer 102 or the via/contact 110 is re-exposed again. The volumetric ratio between hydrofluoric acid and water in the hydrofluoric acid solution is preferably between 1:600 to 1:500 and the cleaning time is roughly 2 minutes.

In the first stage wet etching step 502, the oxidizing agent turns the high molecular weight polymeric compound 120 on the dielectric layer and the organic oxide material on the metallic layer 102 into a water soluble material. Hence, high molecular weight residues and organic compounds are effectively removed. The additional amalgamating agent in the solution for the first stage wet etching step also mixes with metal in the metallic layer to form a protective layer over the metallic layer 102 or the via/contact 110. Hence, over-oxidation of the metallic layer 110 or the via/contact 110 by the oxidizing agent can be prevented. Ultimately, a very thin metal oxide layer is formed over the metallic layer 102 or the via/contact 110 after the first stage wet etching step 502.

The inorganic acid solution used in the second stage wet etching step 504 is able to remove the metal oxide layer formed over metallic layer 102 or the via/contact 110 in the first stage wet etching step 502. Hence, a clean surface of the metallic layer 102 or the via/contact 110 is exposed. Because only a very thin metallic oxide layer is formed in the first stage, over-etching of the metallic layer 102 or the via/contact 110 in the second stage can be avoided.

In summary, the advantages of the invention include:

1. The post-etching cleaning method is able to remove high molecular weight residues and organic material formed after an etching step so that contact resistant of via can be lowered.

2. Excessive etching of the exposed metallic layer at the bottom of a dual damascene opening after a cleaning step is prevented. Ultimately, a planar metallic layer surface is formed.

3. The post-etching cleaning method is able to prevent the undercutting of cap layer because a highly diluted hydrofluoric acid solution is applied for only a brief period.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A post-etching cleaning method for forming a dual damascene structure, comprising the steps of:
providing a substrate having a metallic layer therein and a dielectric layer and a cap layer over the substrate, wherein a dual damascene opening that exposes the metallic layer is also etched in the dielectric layer and the cap layer;
performing a first wet etching using a cleaning solution that contains hydrogen peroxide and benzotriazole; and
performing a second wet etching using a cleaning solution that includes diluted hydrofluoric acid.

2. The cleaning method of claim 1, wherein the volumetric ratio between hydrogen peroxide and water in the cleaning solution is preferably between 1:80 to 1:25.

3. The cleaning method of claim 1, wherein the benzotriazole has a concentration between 0.5 ppm to 5 ppm in the cleaning solution.

4. The cleaning method of claim 1, wherein the volumetric ratio between hydrofluoric acid and water in the cleaning solution is between 1:600 to 1:500.

5. The cleaning method of claim 1, wherein the metallic layer includes a copper layer.

6. The cleaning method of claim 1, wherein material constituting the dielectric layer includes a low dielectric constant spin-coated material.

7. A post-etching cleaning method, comprising the steps of:
providing a substrate having a metallic layer therein and a dielectric layer and a cap layer over the substrate, wherein an opening that exposes the metallic layer is also etched in the dielectric layer and the cap layer;
performing a first wet etching using a cleaning solution that contains an oxidizing agent and a testing agent, wherein the testing agent serves to reduce the oxidation between the oxidizing agent and the metallic layer; and
performing a second wet etching using a cleaning solution that includes inorganic acid solution.

8. The cleaning method of claim 7, wherein the oxidizing agent is a compound for removing the high molecular weight compound and the organic oxide material on the metallic layer formed during the etching step.

9. The cleaning method of claim 8, wherein the oxidizing agent includes hydrogen peroxide.

10. The cleaning method of claim 9, wherein the volumetric ratio between hydrogen peroxide and water in the cleaning solution is preferably between 1:80 to 1:25.

11. The cleaning method of claim 7, wherein the testing agent includes an amalgamating agent that can reduce the intensity of oxidation between the oxidizing agent and the metal in the metallic layer.

12. The cleaning method of claim 11, wherein the amalgamating agent includes benzotriazole.

13. The cleaning method of claim 12, wherein the benzotriazole has a concentration between 0.5 ppm to 5 ppm in the cleaning solution.

14. The cleaning method of claim 7, wherein the inorganic acid solution is used to remove the metallic oxide due to a reaction between the oxidizing agent and the metal in the metallic layer.

15. The cleaning method of claim 7, wherein the inorganic acid solution includes hydrofluoric acid solution.

16. The cleaning method of claim 15, wherein the volumetric ratio between hydrofluoric acid and water is between 1:600 to 1:500.

17. The cleaning method of claim 7, wherein material constituting the dielectric layer includes a low dielectric constant spin-coated material.

18. The cleaning method of claim 7, wherein the metallic layer includes a copper layer.

19. The cleaning method of claim 7, wherein the opening includes a dual damascene opening, a via hole or a contact opening.

20. The cleaning method of claim 7, wherein material constituting the cap layer includes silicon nitride and the etchant used in etching the cap layer includes a difluoromethane/oxygen/argon gaseous mixture.
